(19) United States
(12) Patent Application Publication
(10) Pub. No.: US 2019/0352769 A1
(43) Pub. Date: Nov. 21, 2019

(54) HOUSING OF ELECTRONIC DEVICE AND METHOD FOR MANUFACTURING HOUSING

(71) Applicants: SHENZHEN FUTAIHONG PRECISION INDUSTRY CO., LTD., Shenzhen (CN); FIH (HONG KONG) LIMITED, Kowloon (HK)

(72) Inventors: YU-TSAI WANG, New Taipei (TW); JIAN-FEI JI, Shenzhen (CN); SHUI-YING CHEN, Shenzhen (CN)

(21) Appl. No.: 16/051,063

(22) Filed: Jul. 31, 2018

(30) Foreign Application Priority Data
May 21, 2018 (CN) 201810488729.6

(51) Int. Cl. C23C 14/35; C23C 14/04; H01Q 1/40; C23C 14/50; H05K 3/18

(52) U.S. Cl. CPC C23C 14/351; C23C 14/042; H05K 2201/03; C23C 14/50; H05K 3/18; H01Q 1/40

(57) ABSTRACT

A method for manufacturing a housing of an electronic device includes providing a substrate, forming a metal plating on a surface of the substrate, and laser-etching the metal plating to form a conductive layer. The conductive layer serves as an antenna radiator or a conductive circuit.

### FIELD

The subject matter herein generally relates to electronic devices, and more particularly to a housing of an electronic device and a method of manufacturing the housing.

### BACKGROUND

Generally, antenna structures of mobile devices are made by a laser direct structuring method or made from a flexible printed circuit board. Antennas made by laser direct structuring require a special kind of plastic, which increases a cost of the antenna structure. A flexible printed circuit board requires more space to form the antenna structure.

Therefore, there is room for improvement within the art.

### BRIEF DESCRIPTION OF THE DRAWINGS

Implementations of the present disclosure will now be described, by way of example only, with reference to the attached figures.

FIG. 1 is a cross-sectional view of an embodiment of a housing of an electronic device in accordance with an embodiment of the present disclosure.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “comprising” means “including, but not necessarily limited to”; it specifically indicates open-ended inclusion or membership in a so-described combination, group, series and the like.

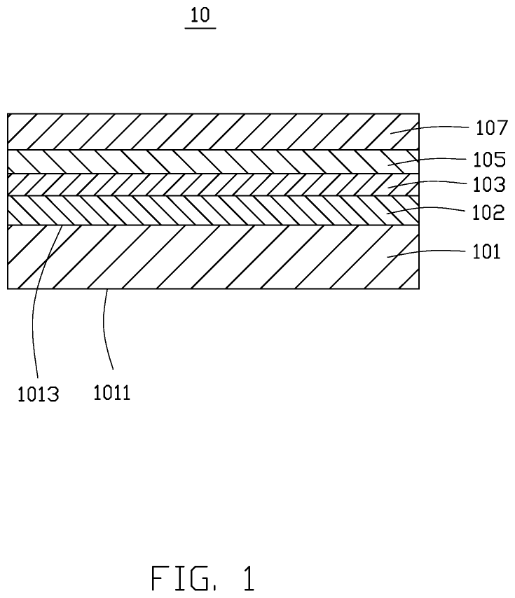

FIG. 1 illustrates an embodiment of a portion of a housing 10. The housing 10 may be a housing of an electronic device, such as a mobile phone, a tablet computer, or the like.

The housing 10 includes at least a substrate 101, a masking layer 103, and a conductive layer 105.

The substrate 101 includes an outer surface 1011 and an opposite inner surface 1013. The outer surface 1011 may be an outer surface of the housing 10. The substrate 101 may be made of ceramic, plastic, or glass. In the following description, the substrate 101 is made of glass.

In at least one embodiment, the housing 10 further includes a color layer 102. The color layer 102 is formed on the inner surface 1013 of the substrate 101. The substrate 101 made of glass allows the color layer 1013 to be viewed through the outer surface 1011 of the substrate 101, thereby improving an outer appearance of the housing 10. A color of the color layer 102 may be selected according to desire.

In detail, the color layer 102 is formed by a magnetron sputtering film on the inner surface 1013 of the substrate 101. A thickness of the color layer is about 1-2 micrometers.

The masking layer 103 is formed on a surface of the color layer 102. A thickness of the masking layer 103 is about 20 micrometers to ensure a masking effect of the masking layer 103 so that internal components of the electronic device located on a surface of the masking layer 103 cannot be seen from outside of the housing 101. A color of the masking layer 103 may be black, blue, or other suitable color having a masking effect.

In at least one embodiment, when the color of the masking layer 103 is black, blue, or other suitable color having a masking effect, the color layer 102 may not be required and can be removed, so that the masking layer 103 is formed on the inner surface 1013 of the substrate 101.

The conductive layer 105 is formed on a surface of the masking layer 103. A thickness of the conductive layer 105 is about 5 micrometers. The conductive layer 105 is made of conductive material. In detail, the conductive layer 105 may be made of metal, such as gold foil, silver foil, copper foil, or aluminum foil. The conductive layer 105 may include a pattern or shape to serve as an antenna radiator or a conductive circuit. Of course, the surface of the masking layer 103 may integrate a wireless charging component, a heat dissipation component, or other functional components of an electronic device to form a multifunctional housing 10.

In at least one embodiment, the housing 10 further includes a protective layer 107 formed on the conductive layer 105 for protecting the conductive layer 105.

In another embodiment, when the substrate 101 is non-transparent, such as when the substrate 101 is made of ceramic or plastic, the color layer 102 and the masking layer 103 may be removed, so that the conductive layer 105 is directly formed on the inner surface 1013 of the substrate 101.

A method for forming the housing 10 is provided.

First, the substrate 101 is provided. The substrate 101 includes an outer surface 1011 and an opposite inner surface 1013. The substrate 101 may be made of ceramic, plastic, or glass. In the following description, the substrate 101 is made of glass.

The substrate 101 is washed. In at least one embodiment, a degreaser is used to clean the surface of the substrate 101.

Plasma technology is further used to clean the substrate 101 and improve surface adherence of the substrate 101.

The color layer 102 is formed on the inner surface 1013 of the substrate 101. A thickness of the color layer 102 is about 1-2 micrometers. In at least one embodiment, the color layer 102 is formed on the inner surface 1013 of the substrate 101 by a magnetron sputtering film. The substrate 101 made of glass allows the color layer 1013 to be viewed through the outer surface 1011 of the substrate 101, thereby improving an outer appearance of the housing 10. A color of the color layer 102 may be selected according to desire.

The masking layer 103 is formed on the surface of the color layer 102. In at least one embodiment, the masking layer 103 is formed on the surface of the color layer 102 by nano-printing technology. A thickness of the masking layer 103 is about 20 micrometers to ensure a masking effect of the masking layer 103 so that internal components of the electronic device located on a surface of the masking layer 103 cannot be seen from outside of the housing 101. A color of the masking layer 103 may be black, blue, or other suitable color having a masking effect.

In at least one embodiment, when the color of the masking layer 103 is black, blue, or other suitable color having a masking effect, the color layer 102 may not be required and can be removed, so that the masking layer 103 is formed on the inner surface 1013 of the substrate 101.

The masking layer 103 is cured by a curing process to increase a binding force of the masking layer 103.

The surface of the masking layer 103 is cleaned. In at least one embodiment, the surface of the masking layer 103 is cleaned by a plasma cleaning technology.

A metal plating is formed on a surface of the masking layer 103. A thickness of the metal plating is about 5 micrometers. In at least one embodiment, the metal plating is formed on the masking layer 103 by ion plating. The metal plating may be made of metal foil, such as gold foil, silver foil, copper foil, or aluminum foil.

The metal plating is laser-etched to form the conductive layer 105. In detail, the metal plating is laser-etched to form the conductive layer 105 having a predetermine pattern or shape to serve as an antenna radiator or conductive circuit.

Of course, the surface of the masking layer 103 may integrate a wireless charging component, a heat dissipation component, or other functional components of an electronic device to form a multifunctional housing 10.

Finally, the protective layer 107 is formed on a surface of the conductive layer 105 to protect the conductive layer 105.

As described above, the housing 10 is able to be formed on the substrate 101 when the substrate 101 is made of different materials, such as ceramic, plastic, or glass. The conductive layer 105 is first formed by an ion plating method to form the metal plating on the inner surface 1013 of the substrate 101, and then by a laser-etching method to laser etch the metal plating to form the conductive layer 105 having a predetermined pattern or shape. The conductive layer 105 serves as an antenna radiator or a conductive circuit. The conductive layer 105 formed as described above has a strong surface adherence, increased surface hardness, and high abrasion resistance. In addition, a micro antenna radiator or conductive circuit is able to be formed. Furthermore, a process of manufacture is stable, low-cost, and environmentally friendly to satisfy 5G network requirements.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A method for manufacturing a housing of an electronic device, the method comprising:
providing a substrate;
forming a metal plating on a surface of the substrate;
laser-etching the metal plating to form a conductive layer, wherein the conductive layer serves as an antenna radiator or a conductive circuit.

2. The method of claim 1, wherein the substrate is made of ceramic, plastic, or glass.

3. The method of claim 1, wherein before the metal plating is formed, a masking layer is formed on an inner surface of the substrate by nano-printing technology; a thickness of the masking layer is 20 micrometers.

4. The method of claim 3, wherein before the masking layer is formed, a color layer is formed on the inner surface of the substrate by a magnetron sputtering film and the color layer is between the substrate and the masking layer; a thickness of the color layer is 1-2 micrometers.

5. The method of claim 1, wherein a thickness of the conductive layer is 5 micrometers.

6. A housing of an electronic device, the housing comprising:
a substrate;
a masking layer formed on a surface of the substrate; and
a conductive layer formed on a surface of the masking layer;
wherein the masking layer comprises a predefined pattern or shape to serve as an antenna radiator or a conductive circuit.

7. The housing of claim 6, wherein the substrate is made of ceramic, plastic, or glass.

8. The housing of claim 6, further comprising a color layer between the substrate and the masking layer, wherein a thickness of the color layer is 1-2 micrometers.

9. The housing of claim 6, wherein a thickness of the masking layer is 20 micrometers.

10. The housing of claim 6, wherein a thickness of the conductive layer is 5 micrometers.
